(19) United States
(12) Patent Application Publication
(10) Pub. No.: US 2023/0184574 A1
(43) Pub. Date: Jun. 15, 2023

(54) APPARATUS AND METHOD OF SUPPLYING CHEMICAL LIQUID AND SUBSTRATE TREATING APPARATUS

(71) Applicant: SEMES CO., LTD., Cheonan-si (KR)

(72) Inventors: Tae Suk YUN, Cheonan-si (KR); Sang Woo Park, Daejeon (KR); Do Gyeong Ha, Daegu (KR); Seung Tae Yang, Yongin-si (KR); Bu Young Jung, Cheonan-si (KR); Moon Soon Choi, Cheonan-si (KR); Chae Young Lim, Cheonan-si (KR)

(73) Assignee: SEMES CO., LTD., Cheonan-si (KR)

(21) Appl. No.: 18/063,881

(22) Filed: Dec. 9, 2022

(30) Foreign Application Priority Data
Dec. 13, 2021 (KR) 10-2021-0178088

(51) Int. Cl. G01F 23/02; B05C 11/10; B05C 5/02

(52) U.S. Cl. CPC G01F 23/02; B05C 11/1026; B05C 5/0225

(57) ABSTRACT

Provided is an apparatus for supplying a chemical liquid, the apparatus including: a storage tank in which a chemical liquid is stored; a discharge line through which the chemical liquid stored in the storage tank is discharged; a level tube connected to the storage tank so as to check a water level of the chemical liquid in the storage tank and receiving the chemical liquid at the same water level as the water level of the chemical liquid in the storage tank; and a controller for controlling a first valve installed in the discharge line, in which the level tube has one end connected to an upper space of the storage tank and the other end connected to the discharge line.

### CROSS-REFERENCE TO RELATED APPLICATIONS

This application claims priority to and the benefit of Korean Patent Application No. 10-2021-0178088 filed in the Korean Intellectual Property Office on Dec. 13, 2021, the entire contents of which are incorporated herein by reference.

### TECHNICAL FIELD

The present invention relates to a substrate treating apparatus and a substrate treating method.

### BACKGROUND ART

In general, in a process of treating a glass substrate or a wafer in a process of manufacturing a flat panel display device or a semiconductor, various processes, such as a photoresist coating process, a developing process, an etching process, and an ashing process, are performed. In each process, in order to remove various contaminants attached to the substrate, a wet cleaning process using a chemical liquid or deionized water and a drying process for drying the chemical liquid or the deionized water left on the surface of the substrate are performed.

Recently, an etching process for selectively removing a silicon nitride layer and a silicon oxide layer by using a chemical used at a high temperature, such as phosphoric acid, is being performed. In the substrate treatment process using high-temperature chemicals, a chemical treatment operation, a rinse treatment operation, and a drying treatment operation are sequentially performed. In the chemical treatment operation, a chemical for etching the thin film formed on the substrate or removing foreign substances on the substrate is supplied to the substrate, and in the rinse treatment operation, a rinse liquid, such as pure water, is supplied onto the substrate.

As described above, a chemical liquid supply apparatus for supplying and circulating various liquid chemicals (hereinafter, collectively referred to as a chemical liquid) is installed in the substrate treating apparatus. The chemical liquid supply apparatus has a structure in which a chemical liquid is supplied to a substrate treating unit from a chemical liquid tank storing a chemical liquid by using a pump or the like, and the used chemical liquid is recovered back to the chemical liquid tank again. The chemical liquid tank is mostly located below a facility frame of the substrate treating apparatus.

In general, various types of sensors may be used to measure the water level of the chemical liquid stored in the chemical liquid tank, and a method of measuring the water level by using the sensor may be divided into a contact measurement method and a non-contact measurement method depending on whether the chemical liquid is in contact with a measurement target.

In the contact measurement method, in the case of a specific chemical liquid that is toxic or corrosive, the exposed part of the sensor is corroded, impurities are absorbed into the chemical liquid, and the purity is lowered, and harmful components of the chemical liquid is exposed, which may cause a problem in stability.

Therefore, in the case of a specific chemical liquid with strong toxicity or corrosiveness, the non-contact measurement method capable of measuring the water level of the chemical liquid without contact with the chemical liquid must be used.

FIG. 10 is a diagram illustrating a non-contact level measuring device.

As illustrated in FIG. 10, in the non-contact level measuring device 1000 a plurality of level sensors 1003 is installed at appropriate positions on a level tube 1002 connecting upper and lower portions of a chemical liquid tank 1001 to detect the presence of a chemical liquid for each position. However, in this method, a phenomenon in which the chemical liquid in the level tube 1002 is stagnant occurs. The stagnant chemical liquid in the level tube 1002 causes a particle source during substrate treatment.

In order to remove the stagnant chemical liquid in the level tube 1002, an all-drain process of draining all the chemical liquid to a tank drain every predetermined time needs to be performed, so that disposal of the chemical liquid causes an increase in chemical liquid consumption.

### SUMMARY OF THE INVENTION

The present invention has been made in an effort to provide a chemical liquid supply apparatus and method capable of removing a stagnant chemical liquid in a level tube, and a substrate treating apparatus.

The present invention has also been made in an effort to provide a chemical liquid supply apparatus and method, and a substrate treating apparatus capable of minimizing the amount of chemical liquid waste.

The object of the present invention is not limited thereto, and other objects not mentioned will be clearly understood by those of ordinary skill in the art from the following description.

An exemplary embodiment of the present invention provides an apparatus for supplying a chemical liquid, the apparatus including: a storage tank in which a chemical liquid is stored; a discharge line through which the chemical liquid stored in the storage tank is discharged; a level tube connected to the storage tank so as to check a water level of the chemical liquid in the storage tank and receiving the chemical liquid at the same water level as the water level of the chemical liquid in the storage tank; and a controller for controlling a first valve installed in the discharge line, in which the level tube has one end connected to an upper space of the storage tank and the other end connected to the discharge line.

Further, the controller may open the first valve for a predetermined time and perform a stagnant chemical liquid drain mode so that the stagnant chemical liquid in the level tube is discharged through the discharge line.

Further, the apparatus may further include a purge gas supply line for supplying purge gas to the level tube.

Further, the purge gas supply line may supply purge gas to pressurize the chemical liquid in a leveling line in the stagnant chemical liquid drain mode.

Further, the level tube may include: a vertically extended leveling line; a first upper line connecting an upper end of the leveling line and an upper space of the storage tank; and a second lower line connecting a lower end of the leveling line and the discharge line.

Further, the apparatus may further include a purge gas supply line connected to a connection portion between the first upper line and the leveling line to supply purge gas to the leveling line.

Further, the apparatus may further include a second valve installed on the first upper line, in which the controller may control the second valve so that the purge gas supplied through the purge gas supply line is provided only to the leveling line in the stagnant chemical liquid drain mode.

Further, the apparatus may further include a branch line branched from a predetermined height of the leveling line and connected to the discharge line, and provided with a third valve, in which the controller opens the third valve in the stagnant chemical liquid drain mode to drain the chemical liquid present at the predetermined height or higher of the leveling line.

Further, the apparatus may further include an exhaust line installed on an upper cover of the storage tank, in which the first upper line may be connected to the exhaust line.

Another exemplary embodiment of the present invention provides a method of supplying a chemical liquid by measuring a level of a chemical liquid by a level tube communicating with a storage tank and located on one side of the storage tank and level sensors located on one side of the level tube, the method including: a chemical liquid drain operation of supplying a chemical liquid stored in the storage tank through a chemical liquid supply line, in which a stagnant chemical liquid in the level tube is drained at regular intervals, in which in the chemical liquid drain operation, a lower end of the level tube is connected to a discharge line of the storage tank, so that when the chemical liquid in the storage tank is discharged, the stagnant chemical liquid in the level tube is drained together.

Further, in the chemical liquid drain operation, the stagnant chemical liquid in the level tube may be pressurized with purge gas.

Further, the valve installed in the upper line of the level tube may be closed so that the purge gas is provided only to the level tube in the chemical liquid drain operation.

Further, in the chemical liquid drain operation, the stagnant chemical in the level tube may be drained only to a water level before a water level set in the level tube.

Still another exemplary embodiment of the present invention provides a substrate treating facility, including: a treating unit for treating a substrate with a chemical liquid; and a chemical liquid solution supply unit for supplying the chemical liquid to the treating unit, in which the chemical liquid supply unit includes: a storage tank in which a chemical liquid is stored; a circulation line connected to the storage tank to circulate the chemical liquid in the storage tank; a pump installed in the circulation line; a chemical liquid supply line branched from the circulation line; a discharge line through which the chemical liquid stored in the storage tank is discharged; a level tube connected to the storage tank so as to check a water level of the chemical liquid in the storage tank and receiving the chemical liquid at the same water level as the water level of the chemical liquid in the storage tank; and a controller for controlling a first valve installed in the discharge line, in which the level tube has one end connected to an upper space of the storage tank and the other end connected to the discharge line.

Further, the controller may open the first valve for a predetermined time and performs a stagnant chemical liquid drain mode so that the stagnant chemical liquid in the level tube is discharged through the discharge line, and control the pump so that the chemical liquid is circulated through the circulation line even when the stagnant chemical liquid drain mode is in progress.

Further, the controller may further include a purge gas supply line for supplying purge gas to the level tube, and the purge gas supply line may supply purge gas to pressurize the chemical liquid in the leveling line in the stagnant chemical liquid drain mode.

Further, the level tube may include: a vertically extended leveling line; a first upper line connecting an upper end of the leveling line and an upper space of the storage tank; and a second lower line connecting a lower end of the leveling line and the discharge line.

Further, the substrate treating facility may further include a purge gas supply line connected to a connection portion between the first upper line and the leveling line to supply purge gas to the leveling line.

Further, the substrate treating facility may further include a second valve installed on the first upper line, in which the controller may control the second valve so that the purge gas supplied through the purge gas supply line is provided only to the leveling line in the stagnant chemical liquid drain mode.

Further, the substrate treating facility may further include a branch line branched from a predetermined height of the leveling line and connected to the discharge line, and provided with a third valve, in which the controller opens the third valve in the stagnant chemical liquid drain mode to drain the chemical liquid present at the predetermined height or higher of the leveling line.

According to the exemplary embodiment of the present invention, it is possible to remove the stagnant chemical liquid in the level tube without stopping the pump operation of the circulation line.

According to the exemplary embodiment of the present invention, it is possible to minimize the amount of chemical waste.

According to the exemplary embodiment of the present invention, it is possible to efficiently manage the chemical liquid.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view schematically illustrating a substrate treating facility provided with a substrate treating apparatus according to an exemplary embodiment of the present invention.

FIG. 2 is a top plan view of the substrate treating apparatus of FIG. 1.

FIG. 3 is a cross-sectional view of the substrate treating apparatus of FIG. 1.

FIG. 4 is a diagram illustrating a chemical liquid supply unit illustrated in FIG. 3.

FIG. 5 is a diagram illustrating the main configuration of the chemical liquid supply unit illustrated in FIG. 4.

FIG. 6 is a diagram illustrating a process in which a chemical liquid of the level tube is drained in the chemical liquid supply unit of FIG. 5.

FIG. 7 is a diagram illustrating a first modified example of the chemical liquid supply unit.

FIG. 8 is a diagram illustrating a process in which the chemical liquid of the level tube is drained in the chemical liquid supply unit of FIG. 7.

FIG. 9 is a diagram illustrating a second modified example of the chemical liquid supply unit.

FIG. 10 is a diagram illustrating a level measuring device of a storage tank in the related art.

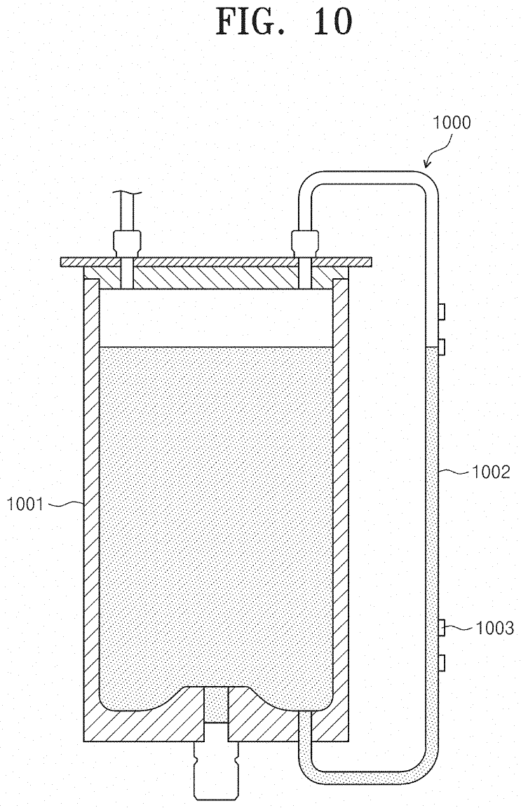

### DETAILED DESCRIPTION

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between ˜” and “just between ˜” or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

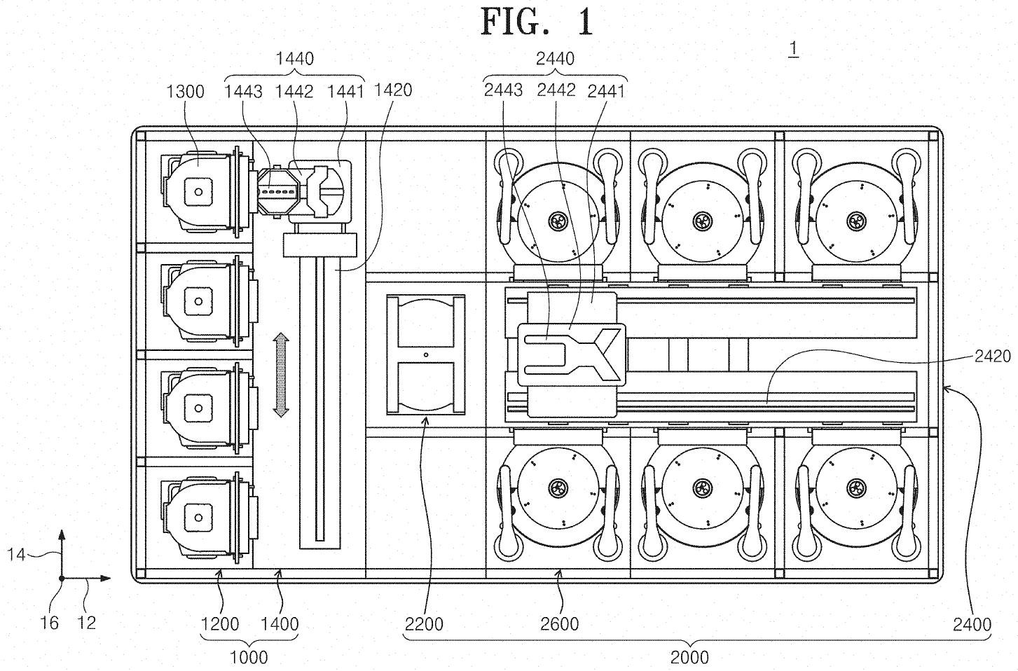

FIG. 1 is a top plan view schematically illustrating a substrate treating facility 1 of the present invention.

Referring to FIG. 1, substrate treating equipment 1 includes an index module 1000 and a process treating module 2000. The index module 1000 includes a load port 1200 and a transfer frame 1400. The load port 1200, the transfer frame 1400, and the process treating module 2000 are sequentially arranged in series. Hereinafter, a direction in which the load port 1200, the transfer frame 1400, and the process treating module 2000 are arranged is referred to as a first direction 12. When viewed above, a direction vertical to the first direction 12 is referred to as a second direction 14, and a direction vertical to a plane including the first direction 12 and the second direction 14 is referred to as a third direction 16.

A carrier 1300 in which a substrate W is accommodated is seated on the load port 1200. The load port 1200 is provided in plurality, and the plurality of load ports 120 is arranged in series in the second direction 14. FIG. 1 illustrates that four load ports 1200 are provided. However, the number of load ports 1200 may also be increased or decreased according to process efficiency of the process treating module 2000 and a condition, such as foot print. A slot (not illustrated) provided to support an edge of the substrate W is formed in the carrier 1300. The slot is provided in plurality in the third direction 16. The substrates W are positioned in the carrier 1300 to be stacked while being spaced apart from each other in the third direction 16. As the carrier 1300, a Front Opening Unified Pod (FOUP) may be used.

The process treating module 2000 includes a buffer unit 2200, a transfer chamber 2400, and a process chamber 2600. A longitudinal direction of the transfer chamber 2400 is parallel to the first direction 12. Process chambers 2600 are disposed at one side and the other side of the transfer chamber 2400 in the second direction 14. The process chambers 2600 positioned at one side of the transfer chamber 2400 and the process chambers 2600 positioned at the other side of the transfer chamber 2400 are provided to be symmetric to each other based on the transfer chamber 2400. Some of the process chambers 2600 are disposed in the longitudinal direction of the transfer chamber 2400. Further, some of the process chambers 2600 are disposed to be stacked with each other. That is, the process chambers 2600 may be disposed in an arrangement of A×B (A and B are natural numbers equal to or greater than 1) at one side of the transfer chamber 2400. Herein, A is the number of process chambers 2600 provided in series in the first direction 12, and B is the number of process chambers 2600 provided in series in the third direction 16. When four or six process chambers 2600 are provided at one side of the transfer chamber 2400, the process chambers 2600 may be disposed in an arrangement of 2×2 or 3×2. The number of process chambers 2600 may be increased or decreased. Contrast to the foregoing, the process chambers 2600 may be provided only at one side of the transfer chamber 2400. Further, contrast to the foregoing, the process chambers 2600 may be provided only at one side and both sides of the transfer chamber 2400 in a single layer.

The buffer unit 2200 is disposed between the transfer frame 1400 and the transfer chamber 2400. The buffer unit 2200 provides a space in which the substrate W stays before the substrate W is transferred between the transfer chamber 2400 and the transfer frame 1400. The buffer unit 2200 is provided with a slot (not illustrated) on which the substrate W is placed therein, and the slots (not illustrated) are provided in plurality so as to be spaced apart from each other in the third direction 16. In the buffer unit 2200, a surface facing the transfer frame 1400 and a surface facing the transfer chamber 2400 are opened.

The transfer frame 1400 transfers the substrate W between the carrier 1300 seated on the load port 1200 and the buffer unit 2200. In the transfer frame 1400, an index rail 1420 and an index robot 1440 are provided. A longitudinal direction of the index rail 1420 is provided to be parallel to the second direction 14. The index robot 1440 is installed on the index rail 1420, and linearly moves in the second direction 14 along the index rail 1420. The index robot 1440 includes a base 1441, a body 1442, and an index arm 1443. The base 1441 is installed to be movable along the index rail 1420. The body 1442 is coupled to the base 1441. The body 1442 is provided to be movable in the third direction 16 on the base 1441. Further, the base 1442 is provided to be rotatable on the base 1441. The index arm 1443 is coupled to the body 1442, and is provided to be movable forward and backward with respect to the body 1442. A plurality of index arms 1443 is provided to be individually driven. The index arms 1443 are arranged to be stacked while being spaced apart from each other in the third direction 16. Some of the index arms 1443 may be used when the substrate W is transferred from the process treating module 2000 to the carrier 1300, and the other may be used when the substrate W is transferred from the carrier 1300 to the process treating module 2000. This may prevent particles generated from the substrate W before the process processing from being attached to the substrate W after the process processing in the process of loading and unloading the substrate W by the index robot 1440.

The transfer chamber 2400 transfers the substrate W between the buffer unit 2200 and the process chamber 2600, and between the process chambers 2600. A guide rail 2420 and a main robot 2440 are provided to the transfer chamber 2400. The guide rail 2420 is disposed so that a longitudinal direction thereof is parallel to the first direction 12. The main robot 2440 is installed on the guide rail 2420, and linearly moves on the guide rail 2420 in the first direction 12. The main robot 2440 includes a base 2441, a body 2442, and a main arm 2443. The base 2441 is installed to be movable along the guide rail 2420. The body 2442 is coupled to the base 2441. The body 2442 is provided to be movable in the third direction 16 on the base 2441. Further, the base 2442 is provided to be rotatable on the base 2441. The main arm 2443 is coupled to the body 2442, and is provided to be movable forward and backward with respect to the body 2442. A plurality of main arms 2443 is provided to be individually driven. The main arms 2443 are arranged to be stacked while being spaced apart from each other in the third direction 16. The main arm 2443 used when the substrate W is transferred from the buffer unit 2200 to the process chamber 2600 may be different from the main arm 2443 used when the substrate W is transferred from the process chamber 2600 to the buffer unit 2200.

A substrate treating apparatus 10 for performing a cleaning process on the substrate W is provided in the process chamber 2600. The substrate treating apparatus 10 provided in each process chamber 2600 may have a different structure according to the type of washing process performed. Optionally, the substrate treating apparatus 10 in each process chamber 2600 may have the same structure. Optionally, the process chambers 2600 may be divided into a plurality of groups, and the substrate treating apparatuses 10 provided in the process chambers 2600 included in the same group may have the same structure, and the substrate treating apparatuses 10 provided in the process chambers 2600 included in the different groups may have the different structures. For example, when the process chambers 2600 are divided into two groups, the process chambers 2600 of a first group may be provided to one side of the transfer chamber 2400, and the process chambers 2600 of a second group may be provided to the other side of the transfer chamber 2400. Optionally, at each of the one side and the other side of the transfer chamber 2400, the process chambers 2600 of the first group may be provided to a lower layer, and the process chambers 2600 of the second group may be provided to an upper layer. The process chambers 2600 of the first group and the process chambers 2600 of the second group may be classified according to the type of chemical used or the type of cleaning method.

In the exemplary embodiment below, an apparatus for cleaning the substrate W by using treatment fluids, such as high-temperature sulfuric acid, high-temperature phosphoric acid, alkaline chemical liquid, acidic chemical liquid, rinse liquid, and drying gas, will be described as an example. However, the technical spirit of the present invention is not limited thereto, and may be applied to various types of devices performing a process while rotating the substrate W, such as an etch process.

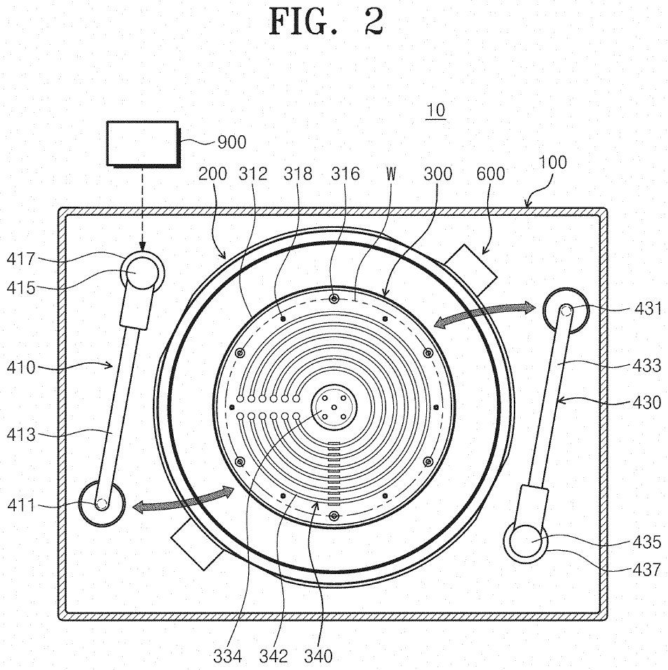

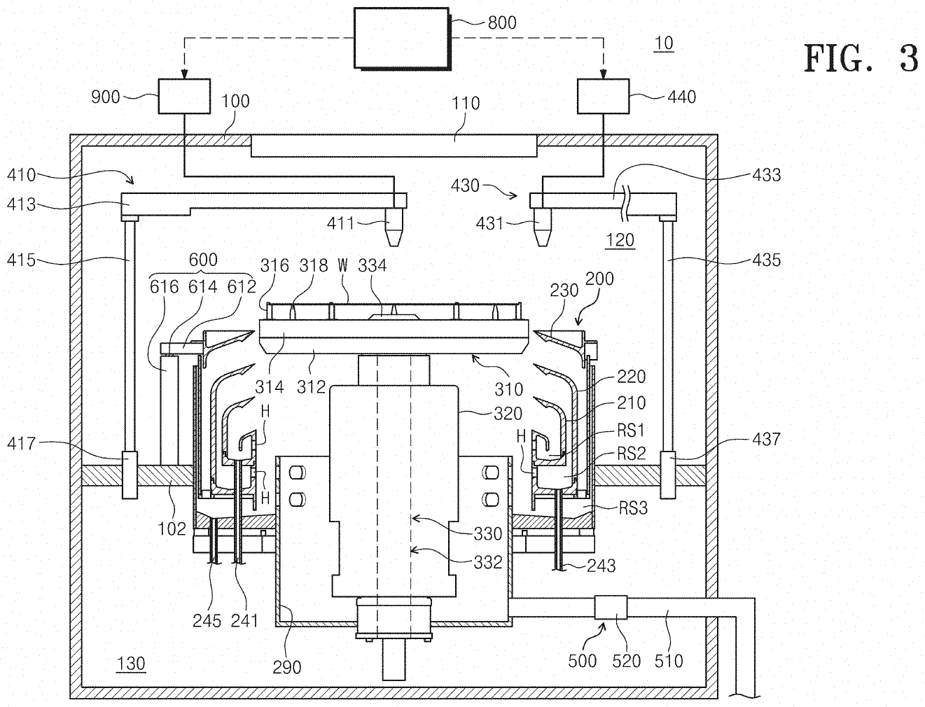

FIG. 2 is a top plan view of the substrate treating apparatus of FIG. 1, and FIG. 3 is a cross-sectional view of the substrate treating apparatus of FIG. 1. Referring to FIGS. 2 and 3, the substrate treating apparatus 10 includes a chamber 100, a bowl 200, a support unit 300, a chemical liquid nozzle unit 410, a rinse liquid nozzle unit 430, and an exhaust unit 500, a lifting unit 600, a sensor unit 700, a chemical liquid supply unit 900, and a controller 800.

The chamber 100 provides a sealed internal space. An airflow supply member 110 is installed on an upper portion of the chamber 100. The airflow supply member 110 forms a descending airflow in the chamber 100.

The airflow supply member 110 filters high-humidity external air and supplies the filtered external air into the chamber 100. The high-humidity external air passes through the airflow supply member 110 and is supplied into the chamber 100 to form descending airflow. The descending airflow provides uniform airflow to the upper portion of the substrate W, and discharges contaminant materials generated in the process of treating the surface of the substrate W by the treatment fluid to the exhaust unit 500 through recovery containers 210,220, and 230 of the bowl 200 together with air.

The chamber 100 is divided into a process area 120 and a maintenance and repair region 130 by a horizontal partition wall 102. In the process region 120, the bowl 200 and the support unit 300 are located. In the maintenance and repair region 130, in addition to the recovery lines 241, 243, and 245 and the exhaust line 510 connected to the bowl 200, a driving unit of the lifting unit 600, a driving unit connected to the chemical liquid nozzle unit 410, a supply line, and the like are located. The maintenance and repair region 130 is isolated from the process region 120.

The bowl 200 has a cylindrical shape having an open upper portion, and has a treatment space for treating the substrate W. The opened upper surface of the bowl 200 is provided as a loading and unloading passage of the substrate W. The support unit 300 is located in the treatment space. The support unit 300 rotates the substrate W in the state of supporting the substrate W during the progress of the process.

The bowl 200 provides a lower space to which the exhaust duct 290 is connected at the lower end so that forced exhaust is made. In the bowl 200, the first to third recovery containers 210, 220, and 230 for introducing and sucking the treatment liquid and gas scattered on the rotating substrate W are arranged in multiple stages.

The annular first to third recovery containers 210, 220, and 230 have exhaust ports H communicating with one common annular space. Specifically, each of the first to third recovery containers cylinders 210, 220, and 230 includes a bottom surface having an annular ring shape and a side wall extending from the bottom surface and having a cylindrical shape. The second recovery container 220 surrounds the first recovery container 210, and is spaced apart from the first recovery container 210. The third recovery container 230 surrounds the second recovery container 220, and is spaced apart from the second recovery container 220.

The first to third recovery containers 210, 220, and 230 provide first to third recovery spaces RS1, RS2, and RS3 into which an airflow containing the treatment liquid and fumes scattered from the substrate W flows. The first recovery space RS1 is defined by the first recovery container 110, the second recovery space RS2 is defined by a spaced space between the first recovery container 210 and the second recovery container 120, and the third recovery space RS3 is defined by a spaced space between the second recovery container 120 and the third recovery container 130.

A central portion of each of the upper surfaces of the first to third recovery containers 210, 220, and 230 is opened. The first to third recovery containers 210, 220, and 230 are formed of inclined surfaces whose distance from the corresponding bottom surface gradually increases from the connected side walls toward the opened portion. The treatment liquid scattered from the substrate W flows into the recovery spaces RS1, RS2, and RS3 along the upper surfaces of the first to third recovery containers 210, 220, and 230.

The first treatment liquid introduced into the first recovery space RS1 is discharged to the outside through a first recovery line 241. The second treatment liquid introduced into the second recovery space RS2 is discharged to the outside through a second recovery line 243. The third treatment liquid introduced into the third recovery space RS3 is discharged to the outside through a third recovery line 245.

The support unit 300 may support the substrate W during the process and may rotate the substrate W during the process.

The support unit 300 includes a support plate 310, a spin driving unit 320, a bag nozzle unit 330, and a heating member 340.

The support plate 310 includes a chuck stage 312 and a quartz window 314. The chuck stage 312 has a circular top surface. The chuck stage 312 is rotated by being coupled to the spin driving unit 320. Chucking pins 316 are installed at the edge of the chuck stage 312. The chucking pins 316 are provided to protrude above the quartz window 314 through the quartz window 314. The chucking pins 316 align the substrate W so that the substrate W supported by the plurality of support pins 318 is in an original position. During the process, the chucking pins 316 come into contact with the side of the substrate W to prevent the substrate W from being separated from the original position.

The quartz window 314 is positioned on the substrate W and the chuck stage 210. A quartz window 314 is provided to protect the heating member 340. The quartz window 314 may be provided transparently. The quartz window 314 may be rotated together with the chuck stage 312. The quartz window 314 includes support pins 318. The support pins 318 are disposed in an edge portion of the upper surface of the quarts window 314 while being spaced apart from each other at a predetermined interval. A support pin 318 is provided to protrude upwardly from the quartz window 314. The support pins 318 support the lower surface of the substrate W, and the substrate W is supported while being spaced apart from the quartz window 314 in the upper direction.

The spin driving unit 320 has a hollow shape and is coupled to the chuck stage 312 to rotate the chuck stage 312. When the chuck stage 312 is rotated, the quartz window 314 may be rotated together with the chuck stage 312. In addition, components provided in the support plate 310 may be positioned independently from rotation of the support plate 310. For example, the heating member 340 to be described later may be positioned independently from the rotation of the support plate 310.

The back nozzle unit 330 is provided to inject the rinse liquid DIW on the rear surface of the substrate W. The back nozzle unit 330 includes a nozzle body 332 and a back nozzle injection unit 334. The back nozzle injection unit 334 is located at the upper center of the chuck stage 312 and the quartz window 314. The nozzle body 332 is installed through the hollow spin driving unit 320, and a rinse liquid moving line, a gas supply line, and a purge gas supply line may be provided inside the nozzle body 332.

The heating member 340 may heat the substrate W during the process progress. The heating member 340 is disposed in the support plate 310. The heating member 340 may include a lamp 342.

The heating member 340 is installed on the chuck stage 312. The heating member 340 may be provided in a ring shape. A plurality of heating members 340 may be provided. The heating members 340 may be provided with different diameters. The temperature of each heating member 340 may be individually controlled. The heating member 340 may be a lamp 342 emitting light. The lamp 342 may be a lamp 342 emitting light having a wavelength in the infrared region. Further, the lamp 342 may be an Infrared Ray (IR) lamp. The lamp 342 may heat the substrate W by emitting infrared rays.

The heating member 340 may be subdivided into a plurality of concentric zones. Each zone may be provided with lamps 342 capable of individually heating each zone. The ramps 342 may be provided in a ring shape concentrically arranged at different radial distances with respect to the center of the chuck stage 312. At this time, the number of lamps 342 may be increased or decreased depending on the desired temperature controlled degree. The heating member 340 may control a temperature of each individual zone to continuously increase or decrease the temperature according to the radius of the substrate W while the process progresses.

The support unit 300 may further include a cooling member (not illustrated), a heat insulating plate (not illustrated), and a heat radiating plate (not illustrated). The cooling member may be disposed in the support plate 310 to supply a cooling fluid into the support plate 310. For example, the cooling member may supply a cooling fluid to a flow path formed in the heat radiating plate.

The heat insulating plate may be disposed in the support plate 310. In addition, the heat insulating plate may be disposed under the heating member 340 in the support plate 310. The insulating plate may be provided with a transparent material. The heat insulating plate is provided with a transparent material so that light emitted from the heating member 340 may pass through the heat insulating plate. In addition, the heat insulating plate may be provided with a material having low thermal conductivity. For example, the heat insulating plate may be provided with a material having lower thermal conductivity than the heat radiating plate. For example, the heat insulating plate may be made of a material including glass. The insulating plate may be provided with a material including neoceram. The heat insulating plate may be provided with a material including glass ceramic. However, the present invention is not limited thereto, and the heat insulating plate may also be made of a material including ceramic.

A reflective plate may be disposed in the support plate 310. In addition, the reflective plate may be disposed under the heat insulating plate in the support plate 310. The reflecting plate may be provided with a material that reflects the light emitted by the heating member 340. The reflective plate may be provided with a material that reflects light having a wavelength in the infrared region. The reflective plate may be made of a material including a metal. The reflective plate may be made of a material including aluminum. The reflective plate may be provided with a material including silver-plated aluminum whose surface is plated with silver (Ag).

The heat radiating plate may dissipate heat transferred from the heat insulating plate to the outside. In addition, a flow path through which the cooling fluid supplied by the cooling member flows may be formed in the heat radiating plate. The heat radiating plate may be disposed in the support plate 310. In addition, the heat radiating may be disposed under the reflective plate in the support plate. The heat radiating plate may be made of a material having high thermal conductivity. For example, the heat radiating plate may be provided with a material having higher thermal conductivity than the above-described heat insulating plate. The heat radiating plate may be provided with a material including a metal. The heat radiating plate may be provided with a material including aluminum and/or silver.

The chemical liquid nozzle unit 410 may process the substrate W by supplying a treatment liquid to the substrate W. The chemical liquid nozzle unit 410 may supply a heated treatment liquid to the substrate W. The treatment liquid may be a high-temperature chemical for etching the surface of the substrate W. According to the exemplary embodiment, the treatment liquid may include phosphoric acid (H₃PO₄).

The chemical liquid nozzle unit 410 may include a first nozzle 411, a nozzle arm 413, a support rod 415, and a nozzle driver 417. The first nozzle 411 receives the treatment liquid through the chemical liquid supply unit 900. The first nozzle 411 discharges the treatment liquid to the surface of the substrate W. The nozzle arm 413 is an arm provided with a long length in one direction, and the first nozzle 411 is mounted at the tip of the nozzle arm 413. The nozzle arm 413 supports the first nozzle 411. The support rod 415 is mounted to a rear end of the nozzle arm 413. The support rod 415 is located in the lower portion of the nozzle arm 413. The support rod 415 is disposed to be perpendicular to the nozzle arm 413. The nozzle driver 417 is provided at the lower end of the support rod 415. The nozzle driver 417 rotates the support rod 415 about the longitudinal direction axis of the support rod 415. With the rotation of the support rod 415, the nozzle arm 413 and the first nozzle 411 swing with respect to the support rod 415 as the axis. The first nozzle 411 may swing between the outside and the inside of the bowl 200. In addition, the first nozzle 411 may swing a section between the center and the edge region of the substrate W to discharge the treatment liquid.

The rinse liquid nozzle unit 430 may include a second nozzle 431, a nozzle arm 433, a support rod 435, and a nozzle driver 437. The second nozzle 431 receives a rinse liquid through the rinse liquid supply unit 440. The second nozzle 431 discharges the rinse liquid DIW to the surface of the substrate W. The nozzle arm 433 is an arm provided with a long length in one direction, and the second nozzle 431 is mounted at the tip of the nozzle arm 433. The nozzle arm 433 supports the second nozzle 431. The support rod 435 is mounted to a rear end of the nozzle arm 433. The support rod 435 is located in the lower portion of the nozzle arm 433. The support rod 435 is disposed to be perpendicular to the nozzle arm 433. The nozzle driver 437 is provided at the lower end of the support rod 435. The nozzle driver 437 rotates the support rod 435 about the longitudinal direction axis of the support rod 435. With the rotation of the support rod 435, the nozzle arm 433 and the second nozzle 431 swing with respect to the support rod 435 as the axis. The second nozzle 431 may swing between the outside and the inside of the bowl 200.

The exhaust unit 500 may exhaust the inside of the bowl 100. As an example, the exhaust unit 500 is to provide an exhaust pressure (suction pressure) to the recovery containers for recovering the treatment liquid from among the first to third recovery containers 210, 220, and 230 during the process. The exhaust unit 500 includes an exhaust line 510 connected to an exhaust duct 290, and a damper 520. The exhaust line 510 receives exhaust pressure from an exhaust pump (not illustrated) and is connected with a main exhaust line embedded in a bottom space of a semiconductor production line.

In the meantime, the bowl 200 is coupled with the lifting unit 600 which changes a vertical position of the bowl 200. The lifting unit 600 linearly moves the bowl 200 in a vertical direction. According to the vertical movement of the bowl 200, a relative height of the bowl 200 with respect to the support unit 300 is changed.

The lifting unit 600 includes a bracket 612, a movement shaft 614, and a driver 616. The bracket 612 is fixedly installed on the outer wall of the treating container 100. The movement shaft 614 which moves in the vertical direction by the driver 616 is fixedly coupled to the bracket 612. When the substrate W is loaded in or unloaded from the support unit 300, the bowl 200 descends so that the support unit 300 protrudes above the bowl 200. In addition, the height of the bowl 200 is adjusted so that the treatment liquid may be introduced into the predetermined recovery containers 210, 220, and 230 according to the type of the treatment liquid supplied to the substrate W during the process. The bowl 200 may have different types of treatment liquid and pollutant gas recovered for each recovery space RS1, RS2, and RS3.

The controller 800 may control the chemical liquid nozzle unit 410 and the rinse liquid nozzle unit 430 so that the chemical liquid nozzle unit 410 supplies the treatment liquid to the substrate first and then supplies the rinse liquid to the substrate. The controller 800 may control the support unit 300 so that the rotation speed of the substrate when the rinse liquid is supplied is faster than the rotation speed of the substrate when the treatment liquid is supplied.

The controller 800 may control the substrate treating apparatus. The controller 800 may control the components of the process chamber to treat the substrate according to the setting process as described above. Further, the controller 800 may include a process controller formed of a microprocessor (computer) executing the control of the substrate treating apparatus, a user interface formed of a keyboard through which an operator performs a command input manipulation and the like for managing the substrate treating apparatus, a display for visualizing and displaying an operation situation of the substrate treating apparatus, or the like, and a storage unit in which a control program for executing the processing executed in the substrate treating apparatus under the control of the process controller or various data and a program, that is, a processing recipe, for executing processing on each configuration according to processing conditions are stored. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

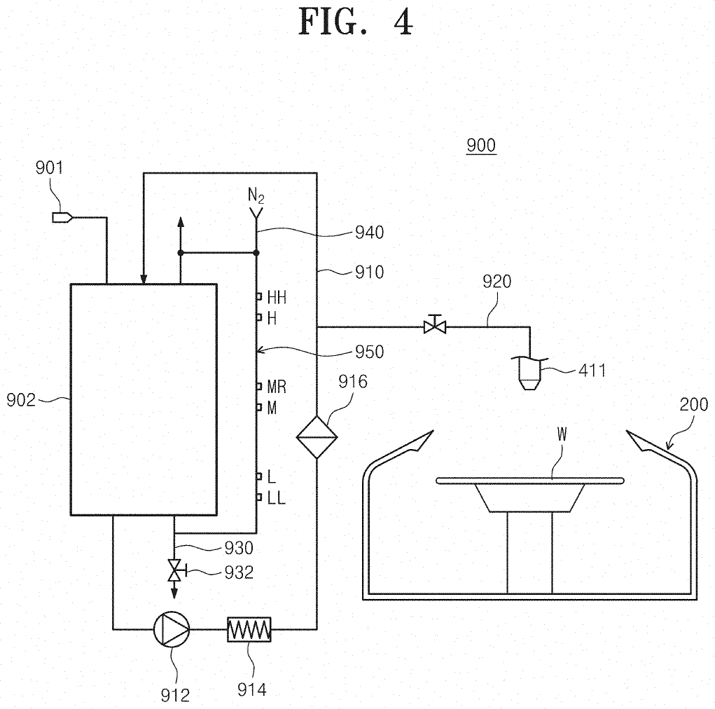

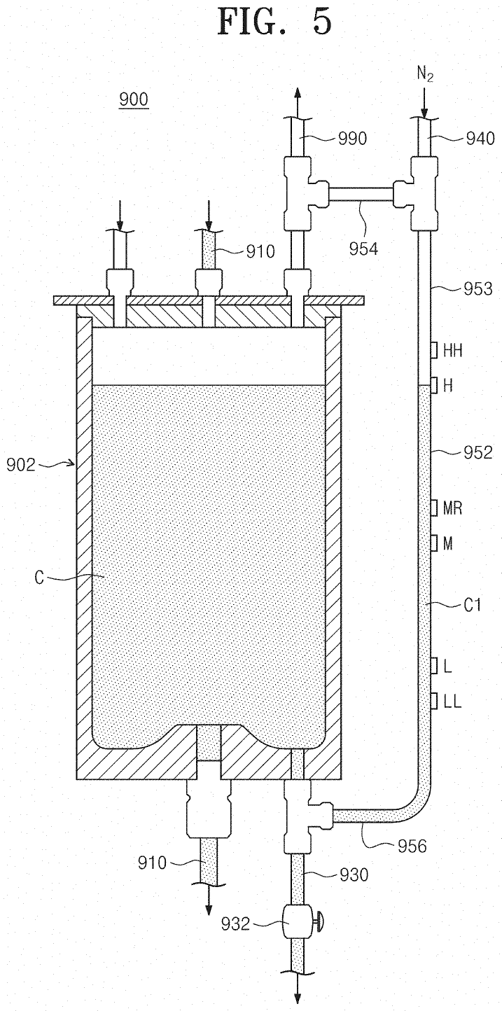

FIG. 4 is a diagram illustrating the chemical liquid supply unit illustrated in FIG. 3, and FIG. 5 is a diagram illustrating the main configuration of the chemical liquid supply unit illustrated in FIG. 4.

Referring to FIGS. 4 and 5, the chemical liquid supply unit 900 may include a storage tank 902, a circulation line 910, a pump 912, a chemical liquid supply line 920, a discharge line 930, a purge gas supply line 940, and a level tube 950.

The storage tank 902 has an accommodation space in which the chemical liquid provided from a chemical liquid supply source 901 is stored. The circulation line 910 circulates the chemical liquid accommodated in the accommodation space. A circulation line 910 may be connected each of to an upper end and a lower end of the treatment tank 902. A pump 912, a heater 914, and a filter 916 may be installed in the circulation line 910. The pump 912 presses the circulation line 910 so that the treatment liquid accommodated in the accommodation space is circulated through the circulation line 910. The heater 914 heats the treatment liquid circulated in the circulation line 910. The heater 914 heats the treatment liquid to a process temperature or higher.

The chemical liquid supply line 920 may supply the chemical liquid to the nozzle 411. The chemical liquid supply line 920 is provided as a branch line branched from the circulation line 910. The chemical liquid supply line 920 is branched from the circulation line 920 and connected to the nozzle 411. Accordingly, the chemical liquid accommodated in the accommodation space may be supplied to the nozzle 411 sequentially through the circulation line 910 and the chemical liquid supply line 920.

A discharge line 930 is connected to the storage tank 902. The chemical liquid in the storage tank 902 may be drained through the discharge line 930. A first valve 932 is installed in the discharge line 930. The chemical liquid in the storage tank is discharged or blocked according to the on/off of the first valve 932.

The level tube 950 communicating with the storage tank 902 is installed on one side of the storage tank 902. The level tube 950 accommodates the chemical liquid at the same water level as that of the chemical liquid in the storage tank 902 so as to check the water level of the chemical liquid in the storage tank 902.

The level tube 950 is also connected in parallel with the storage tank 902 for storing the chemical liquid C, and a portion of the chemical liquid may be introduced according to the water level of the chemical liquid stored in the storage tank 902. That is, the level tube 950 is connected to the upper and lower portions of the storage tank 902 in a bypass manner so that the water level of the chemical liquid inside the storage tank 902 may be easily measured from the outside of the storage tank 902.

In this case, the water level of the chemical liquid C1 inside the level tube 950 may change in association with the water level of the chemical liquid C inside the chemical liquid tank 20, and the relationship between the water level of the chemical liquid C1 inside the level tube 950 and the water level of the chemical liquid C inside the chemical liquid tank 20 may be determined according to the condition, such as the shape and size of the storage tank 902, and the shape of the water level tube 950. The relationship between the level of the chemical liquid C1 inside the level tube 950 and the level of the chemical liquid C inside the chemical liquid tank 902 may be preset. The level tube 950 may have a substantially cylindrical long tube shape, but is not limited thereto.

On the other hand, the material of the level tube 950 may use a transparent glass material or a synthetic resin material, preferably PFA (PerFluoroAlkoxy) that is a type of Teflon fluororesin that is strong against corrosion. In this case, when a transparent PFA tube is used, the level of the chemical liquid may be easily checked from the outside.

On the other hand, the level tube 950 is provided with level sensors 953 for measuring the level of the chemical liquid to measure the level of the chemical liquid stored in the storage tank 902. The level sensor 953 may be a non-contact sensor capable of measuring without directly contacting the chemical liquid. Preferably, the level sensor 953 may measure the level of the chemical liquid introduced into the level tube 950 by using a current value outputted while being changed according to the water level of the chemical liquid introduced into the level tube 950. This method may use the same principle as the capacitive method of sensing an object using a capacitive sensor. In addition, as the level sensor, various non-contact sensors, such as a radar method, a laser method, a load cell method, a nuclear method, and an ultrasonic method, may be applied.

In this exemplary embodiment, the level sensor 953 is disposed at six locations to measure six levels of HH, H, MR, M, L, and LL. It is a matter of course that the number and position of the level sensors 953 may be various as needed.

The level tube 950 includes a leveling line 952 extending vertically, and a first upper line 954 connecting to an upper end of the leveling line 952 and the upper space of the storage tank 902, and a second lower line 956 connecting a lower end of the levelling line 952 and the discharge line 930. The first upper line 954 may be connected to the exhaust line 990 of the storage tank. Further, a connection point of the second lower line 956 and the discharge line 930 may be located between the first valve 932 and the storage tank 902.

The purge gas supply line 940 may be connected to a connection point of the leveling line 952 and the first upper line 954. The purge gas supply line 940 may supply purge gas to the level tube 950. The purge gas supplied through the purge gas supply line 940 pressurizes the chemical liquid in the leveling line 952 in a stagnant chemical liquid drain mode. Therefore, when the first valve 932 is opened and the chemical liquid is drained, the chemical liquid in the level tube 950 may be drained faster than the chemical liquid in the storage tank 902. Therefore, it is possible to reduce the amount of chemical waste in the process of removing the chemical liquid C1 in the level tube 950.

The purge gas supplied through the purge gas supply line 940 may also be provided to the upper space of the storage tank 902. The purge gas purges the upper space of the storage tank 902, and when the inside of the storage tank 902 has a predetermined pressure, the purge gas may be exhausted to the outside through the exhaust line 990. The purge gas may be inert gas.

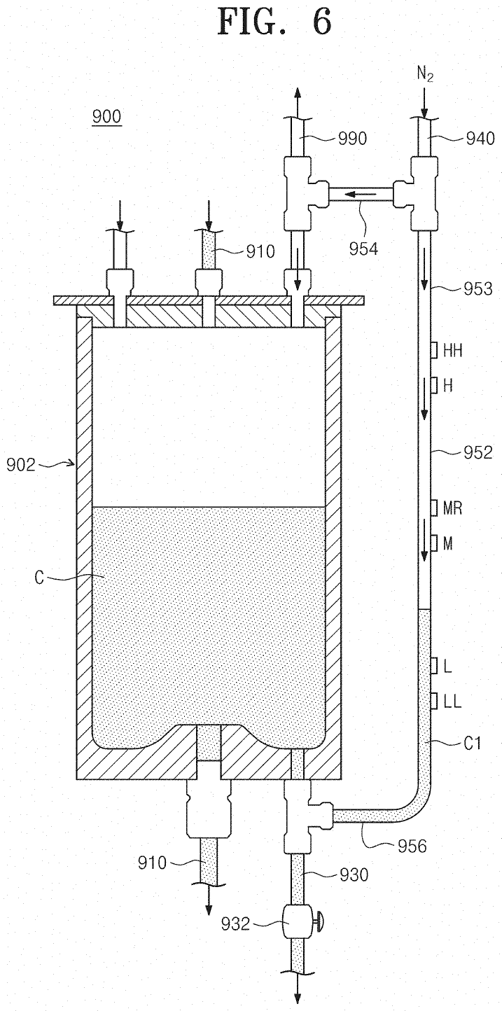

The controller 800 may control the first valve 932 installed in the discharge line 930. FIG. 6 is a diagram illustrating a process in which a chemical liquid of the level tube is drained in the stagnant chemical liquid drain mode.

As illustrated in FIG. 6, the controller 800 opens the first valve 932 for a predetermined period of time to perform the stagnant chemical liquid drain mode so that the stagnant chemical liquid C1 in the level tube 950 is discharged through the discharge line 930. When the water level of the stagnant chemical liquid C1 in the level tube 950 falls below the L level in the stagnant chemical liquid drain mode, the pump running may stop, so that it is preferable that the chemical liquid drain is performed only until the chemical liquid C1 level reaches the L level. The chemical liquid in the storage tank 902 is circulated through the circulation line 910 while the stagnant chemical liquid C1 in the level tube 950 is discharged through the discharge line 930.

The chemical liquid supply unit having the above-described configuration circulates the chemical liquid stored in the storage tank through the circulation line, and performs a chemical liquid drain operation of draining the stagnant chemical liquid in the level tube at regular intervals. In the chemical liquid drain operation, the lower end of the level tube is connected to the discharge line of the storage tank, so that when the first valve is opened, the stagnant chemical liquid in the level tube may be drained.

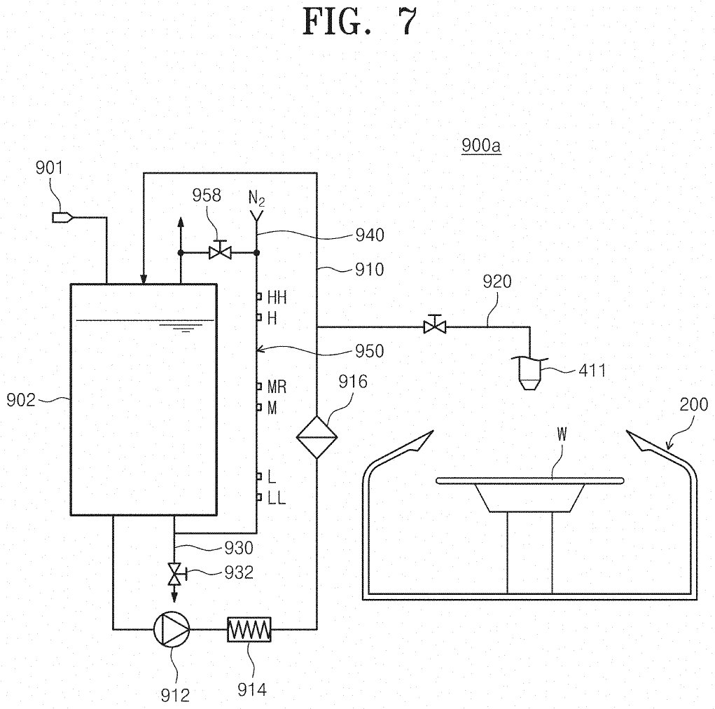

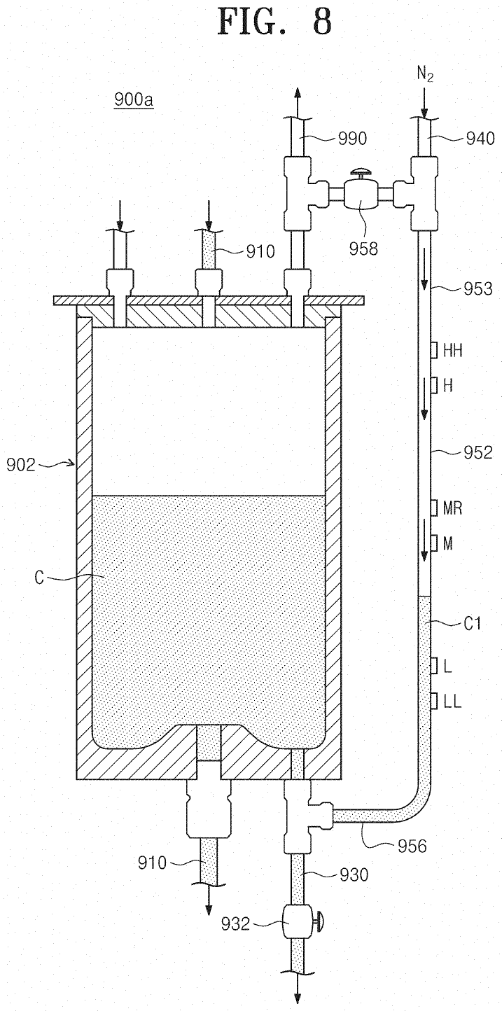

FIG. 7 is a diagram illustrating a first modified example of the chemical liquid supply unit, and FIG. 8 is a diagram illustrating a process in which the chemical liquid of the level tube is drained in the chemical liquid supply unit of FIG. 7.

Referring to FIGS. 7 and 8, a chemical liquid supply unit 900a according to a first modified example is characterized in that a second valve 958 is installed on a first upper line 954. The controller 800 may turn off the second valve 958 so that the purge gas supplied through the purge gas supply line 940 is provided only to the leveling line 952 in the stagnant chemical liquid drain mode.

As described above, since the purge gas is provided only to the leveling line 952, the chemical liquid in the leveling line 952 may be drained more quickly.

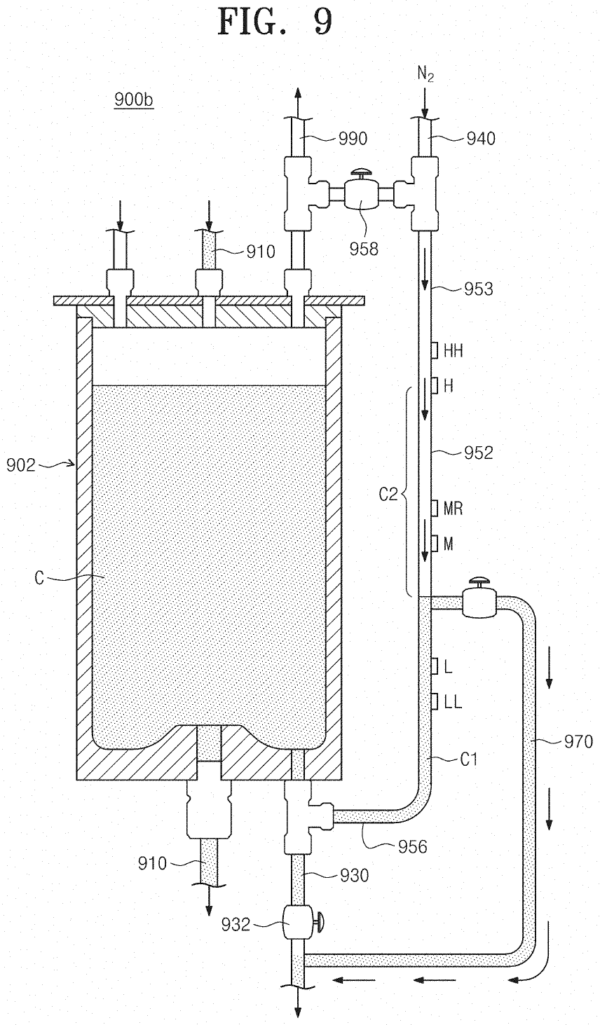

FIG. 9 is a diagram illustrating a second modified example of the chemical liquid supply unit.

Referring to FIG. 9, a chemical liquid supplying device 900b according to a second modified example is characterized in that the chemical liquid supplying device 900b further includes a branch line 970. The branch line 970 is branched from a predetermined height of the leveling line 952 and is connected to the discharge line 930. A third valve 972 may be installed in the branch line 970. A branching point of the branch line 970 may be between the M level and the L level of the leveling line 952. Further, a merging point of the branch line 970 may be a point passing the first valve 932.

In the drain of the chemical liquid of the level tube in the chemical liquid supply device as described above, when the first valve closes and the third valve opens, the chemical liquid in the C2 section is trained through the branch line.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for supplying a chemical liquid, the apparatus comprising:
a storage tank in which a chemical liquid is stored;
a discharge line through which the chemical liquid stored in the storage tank is discharged;
a level tube connected to the storage tank so as to check a water level of the chemical liquid in the storage tank and receiving the chemical liquid at the same water level as the water level of the chemical liquid in the storage tank; and
a controller for controlling a first valve installed in the discharge line,
wherein the level tube has one end connected to an upper space of the storage tank and the other end connected to the discharge line.

2. The apparatus of claim 1, wherein the controller opens the first valve for a predetermined time and performs a stagnant chemical liquid drain mode so that the stagnant chemical liquid in the level tube is discharged through the discharge line.

3. The apparatus of claim 2, further comprising:
a purge gas supply line for supplying purge gas to the level tube.

4. The apparatus of claim 3, wherein the purge gas supply line supplies purge gas to pressurize the chemical liquid in a leveling line in the stagnant chemical liquid drain mode.

5. The apparatus of claim 2, wherein the level tube includes:
a vertically extended leveling line;
a first upper line connecting an upper end of the leveling line and an upper space of the storage tank; and
a second lower line connecting a lower end of the leveling line and the discharge line.

6. The apparatus of claim 5, further comprising:
a purge gas supply line connected to a connection portion between the first upper line and the leveling line to supply purge gas to the leveling line.

7. The apparatus of claim 6, further comprising:
a second valve installed on the first upper line,
wherein the controller controls the second valve so that the purge gas supplied through the purge gas supply line is provided only to the leveling line in the stagnant chemical liquid drain mode.

8. The apparatus of claim 5, further comprising:
a branch line branched from a predetermined height of the leveling line and connected to the discharge line, and provided with a third valve,
wherein the controller opens the third valve in the stagnant chemical liquid drain mode to drain the chemical liquid present at the predetermined height or higher of the leveling line.

9. The apparatus of claim 5, further comprising:
an exhaust line installed on an upper cover of the storage tank,
wherein the first upper line is connected to the exhaust line.

10.-13. (canceled)

14. A substrate treating facility, comprising:
a treating unit for treating a substrate with a chemical liquid; and
a chemical liquid solution supply unit for supplying the chemical liquid to the treating unit,
wherein the chemical liquid supply unit includes:
a storage tank in which a chemical liquid is stored;
a circulation line connected to the storage tank to circulate the chemical liquid in the storage tank;
a pump installed in the circulation line;
a chemical liquid supply line branched from the circulation line;
a discharge line through which the chemical liquid stored in the storage tank is discharged;
a level tube connected to the storage tank so as to check a water level of the chemical liquid in the storage tank and receiving the chemical liquid at the same water level as the water level of the chemical liquid in the storage tank; and
a controller for controlling a first valve installed in the discharge line,
wherein the level tube has one end connected to an upper space of the storage tank and the other end connected to the discharge line.

15. The substrate treating facility of claim 14, wherein the controller opens the first valve for a predetermined time and performs a stagnant chemical liquid drain mode so that the stagnant chemical liquid in the level tube is discharged through the discharge line, and
controls the pump so that the chemical liquid is circulated through the circulation line even when the stagnant chemical liquid drain mode is in progress.

16. The substrate treating facility of claim 15, wherein the controller further includes a purge gas supply line for supplying purge gas to the level tube, and
the purge gas supply line supplies purge gas to pressurize the chemical liquid in the leveling line in the stagnant chemical liquid drain mode.

17. The substrate treating facility of claim 15, wherein the level tube includes:
a vertically extended leveling line;
a first upper line connecting an upper end of the leveling line and an upper space of the storage tank; and
a second lower line connecting a lower end of the leveling line and the discharge line.

18. The substrate treating facility of claim 17, further comprising:
a purge gas supply line connected to a connection portion of the first upper line and the leveling line to supply purge gas to the leveling line.

19. The substrate treating facility of claim 18, further comprising:
a second valve installed on the first upper line,
wherein the controller controls the second valve so that the purge gas supplied through the purge gas supply line is provided only to the leveling line in the stagnant chemical liquid drain mode.

20. The substrate treating facility of claim 17, further comprising:
a branch line branched from a predetermined height of the leveling line and connected to the discharge line, and provided with a third valve,
wherein the controller opens the third valve in the stagnant chemical liquid drain mode to drain the chemical liquid present at the predetermined height or higher of the leveling line.
